(19) United States
(12) Patent Application Publication
(10) Pub. No.: US 2025/0379170 A1
(43) Pub. Date: Dec. 11, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventor: IL HWAN KIM, Suwon-si (KR)

(21) Appl. No.: 19/055,644

(22) Filed: Feb. 18, 2025

(30) Foreign Application Priority Data
Jun. 5, 2024 (KR) 10-2024-0073954

(51) Int. Cl. H01L 23/00; H01L 23/48; H01L 25/11; H10B 80/00

(52) U.S. Cl. CPC H01L 24/08; H01L 24/05; H01L 24/09; H01L 25/117; H01L 23/481; H01L 2224/05576; H01L 2224/05647; H01L 2224/05666; H01L 2224/05681; H01L 2224/08145; H01L 2224/09181; H10B 80/00

(57) ABSTRACT

A semiconductor package includes: first to third semiconductor dies sequentially stacked on each other; and a mold layer covering the first to third semiconductor dies, wherein the second semiconductor die includes a first back-side conductive pad disposed in a top portion thereof, the third semiconductor die includes a first front-side conductive pad, which is disposed in a bottom portion thereof and is in contact with the first back-side conductive pad, each of the first front-side conductive pad and the first back-side conductive pad includes a first metal, and the first front-side conductive pad further includes a second metal that is different from the first metal.

### CROSS-REFERENCE TO RELATED APPLICATION

This U.S. non-provisional patent application claims priority under 35 U.S.C. § 119 to Korean Patent Application No. 10-2024-0073954, filed on Jun. 5, 2024, in the Korean Intellectual Property Office, the disclosure of which is incorporated by reference herein in its entirety.

### TECHNICAL FIELD

Embodiments of the present inventive concept relates to a semiconductor package and a method of fabricating the same.

### DISCUSSION OF THE RELATED ART

Generally, a semiconductor package is configured to facilitate the use of an integrated circuit chip as a component in an electronic product. In general, the semiconductor package may include a substrate (e.g., a printed circuit board, a redistribution substrate, or a buffer die) and a semiconductor chip, which is mounted on the substrate and is electrically connected to the substrate by using, for example, bonding wires or bumps. Typically, the semiconductor package may include a plurality of memory chips. With the continuous development and evolution of the electronic industry, the semiconductor package has been under development to increase reliability and durability.

### SUMMARY

According to an embodiment of the present inventive concept, a semiconductor package includes: first to third semiconductor dies sequentially stacked on each other; and a mold layer covering the first to third semiconductor dies, wherein the second semiconductor die includes a first back-side conductive pad disposed in a top portion thereof, the third semiconductor die includes a first front-side conductive pad, which is disposed in a bottom portion thereof and is in contact with the first back-side conductive pad, each of the first front-side conductive pad and the first back-side conductive pad includes a first metal, and the first front-side conductive pad further includes a second metal that is different from the first metal.

According to an embodiment of the present inventive concept, a semiconductor package includes: a first semiconductor die; a plurality of second semiconductor dies stacked on the first semiconductor die; and a mold layer covering side surfaces of the second semiconductor dies and a top surface of the first semiconductor die, wherein each of the second semiconductor dies includes: a semiconductor substrate having a front surface and a rear surface, which are opposite to each other; a front-side conductive pad disposed on the front surface of the semiconductor substrate; a front-side diffusion barrier layer covering the front-side conductive pad; a back-side conductive pad disposed on the rear surface of the semiconductor substrate; and a back-side diffusion barrier layer covering of the back-side conductive pad, wherein each of the front-side conductive pad and the back-side conductive pad includes a first metal, the back-side diffusion barrier layer includes a second metal that is different from the first metal, and the front-side diffusion barrier layer includes a third metal that is different from each of the first and second metals.

According to an embodiment of the present inventive concept, a semiconductor package includes: a buffer die; outer connection terminals bonded to a first surface of the buffer die; a plurality of first memory dies stacked on the buffer die; a second memory die disposed on an uppermost one of the first memory dies; a dummy die disposed on the second memory die; an adhesive layer disposed between the dummy die and the second memory die; and a mold layer covering side surfaces of the first and second memory dies, the dummy die, and the adhesive layer and a top surface of the buffer die, wherein each of the first memory dies includes: a semiconductor substrate having a front surface and a rear surface, which are opposite to each other; an interlayer insulating layer covering the front surface of the semiconductor substrate; interconnection lines disposed in the interlayer insulating layer; a front-side protection layer covering the interlayer insulating layer; a front-side conductive pad disposed in the front-side protection layer; a front-side diffusion barrier layer covering the front-side conductive pad; a through via penetrating the semiconductor substrate and connected to one of the interconnection lines; a back-side protection layer covering the rear surface of the semiconductor substrate; a back-side conductive pad disposed in the back-side protection layer; and a back-side diffusion barrier layer covering the back-side conductive pad, wherein the first semiconductor substrate has a first thickness, the dummy die has a second thickness that is larger than the first thickness, the front-side conductive pad includes titanium, and a concentration of the titanium in the front-side conductive pad decreases as a distance to the interlayer insulating layer decreases.

According to an embodiment of the present inventive concept, a method of fabricating a semiconductor package includes: preparing a device wafer that has a front surface and a rear surface, which are opposite to each other; sequentially stacking a first metal layer and a second metal layer on the front surface of the device wafer; preparing a carrier substrate; sequentially stacking a third metal layer and a fourth metal layer on the carrier substrate; inverting the device wafer to bring the second metal layer, which is disposed on the device wafer, into contact with the fourth metal layer that is disposed on the carrier substrate; performing a thermocompression process to bond the second metal layer, which is disposed on the device wafer, to the fourth metal layer, which is disposed on the carrier substrate; performing a back grinding process on the rear surface of the device wafer to remove a portion of the device wafer; removing the carrier substrate; and removing the first to fourth metal layers.

In an embodiment of the present inventive concept, the device wafer further includes front-side conductive pads that are disposed on a front surface thereof, and the removing of the first to fourth metal layers exposes the front-side conductive pads.

In an embodiment of the present inventive concept, the first metal layer includes a metal having an etch selectivity with respect to the second metal layer and the front-side conductive pads.

In an embodiment of the present inventive concept, the device wafer further includes through vias, which are connected to the front-side conductive pads, and the method further includes forming back-side conductive pads, which are connected to the through vias, on the rear surface of the device wafer, after performing the back grinding process on the rear surface of the device wafer and before the removing of the carrier substrate.

In an embodiment of the present inventive concept, the device wafer includes device regions and a separation region between the device regions, and the method further includes, after the removing of the first to fourth metal layers, cutting the separation region of the device wafer to form a plurality of semiconductor dies; stacking the semiconductor dies; and performing a thermocompression process to bond the semiconductor dies to each other.

In an embodiment of the present inventive concept, an edge trimming process is performed to remove an edge region of the device wafer and a portion of an edge region of the carrier substrate, after performing the thermocompression process.

In an embodiment of the present inventive concept, an edge trimming process is performed to remove an edge region of the device wafer, before the sequential stacking of the first and second metal layers on the front surface of the device wafer.

In an embodiment of the present inventive concept, an adhesion force that is between the first metal layer and a surface of the device wafer is different from an adhesion force that is between the second metal layer and a surface of the device wafer.

### BRIEF DESCRIPTION OF THE DRAWINGS

FIG. 1 is a cross-sectional view illustrating a semiconductor package according to an embodiment of the present inventive concept.

FIGS. 2A and 2B are enlarged cross-sectional views illustrating a portion ‘Pl’ of FIG. 1.

FIG. 3 is a cross-sectional view illustrating a semiconductor package according to an embodiment of the present inventive concept.

FIGS. 4A and 4B are enlarged sectional views illustrating a portion ‘P2’ of FIG. 3.

FIG. 5 is a cross-sectional view illustrating a semiconductor package according to an embodiment of the present inventive concept.

FIGS. 6A, 6B, 6C, 6D, 6E, 6F, 6G, 6H, 61, 6J, 6K, and 6L are cross-sectional views illustrating a process of fabricating the semiconductor dies of FIG. 1 or 3.

FIG. 7A is an enlarged cross-sectional view illustrating a portion ‘P3’ of FIG. 6A.

FIG. 7B is an enlarged cross-sectional view illustrating a portion ‘P3’ of FIG. 6J.

FIG. 7C is an enlarged cross-sectional view illustrating a portion ‘P3’ of FIG. 6K.

FIGS. 8A and 8B are cross-sectional views illustrating a process of fabricating the semiconductor dies of FIG. 1 or 3.

### DETAILED DESCRIPTION OF THE EMBODIMENTS

Example embodiments of the present inventive concept will now be described more fully with reference to the accompanying drawings. The same reference numerals may refer to the same elements throughout the specification and drawings, and thus, their descriptions that are redundant may be omitted. In the following description, singular expressions may include plural expressions unless the context clearly dictates otherwise.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention. It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

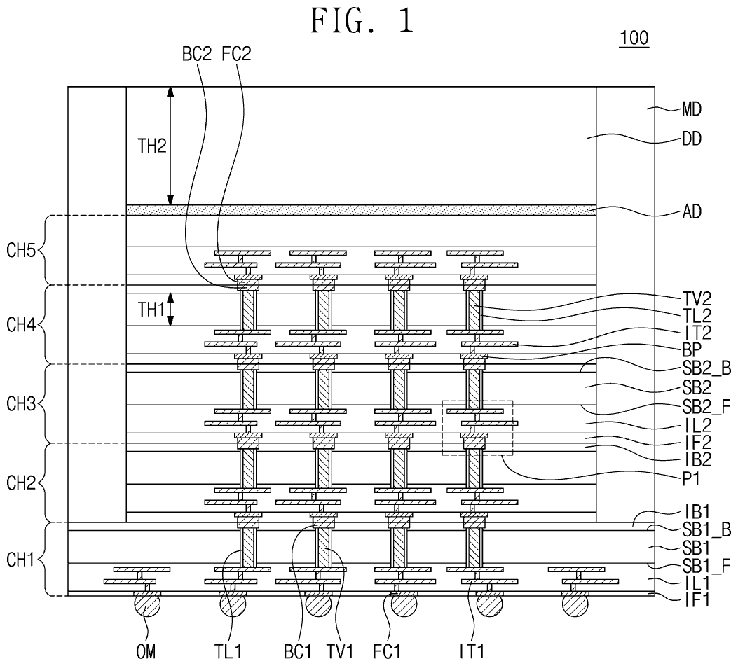

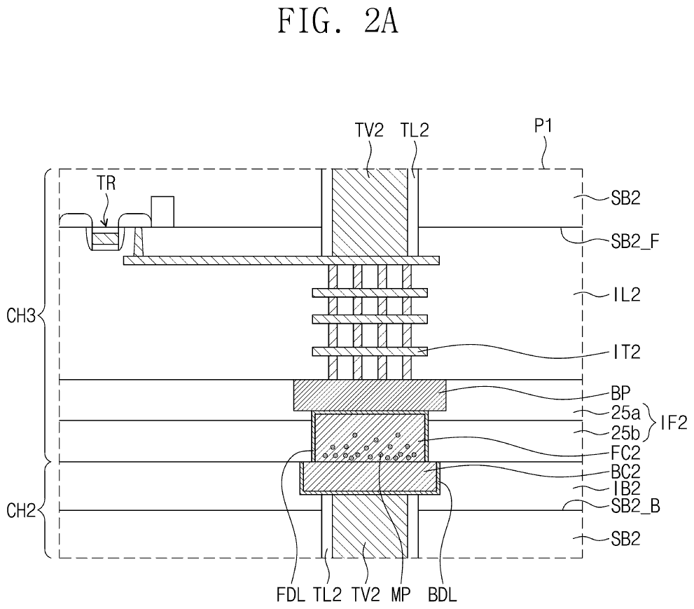

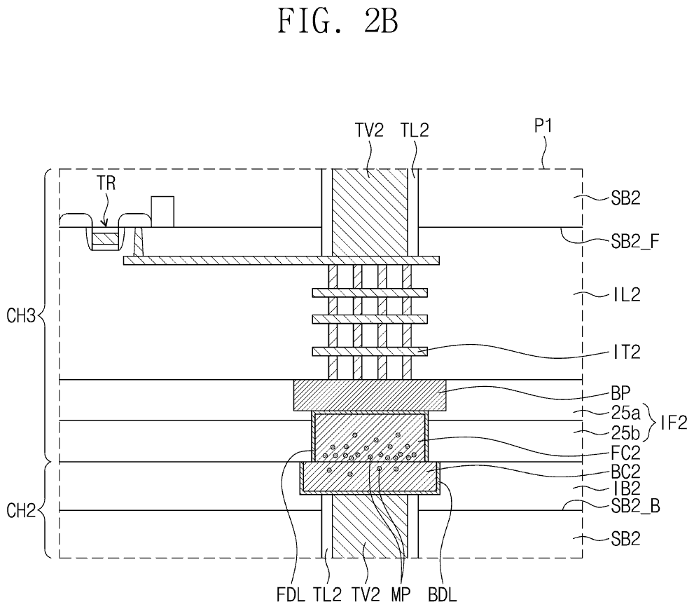

FIG. 1 is a sectional view illustrating a semiconductor package according to an embodiment of the present inventive concept. FIGS. 2A and 2B are enlarged sectional views illustrating a portion ‘P1’ of FIG. 1.

Referring to FIGS. 1, 2A, and 2B, a semiconductor package 100 according to the present embodiment may include first to fifth semiconductor dies CH1 to CH5, which are sequentially stacked, and a mold layer MD that is disposed on side surfaces of the second to fifth semiconductor dies CH2 to CH5 and a top surface of the first semiconductor die CH1. Each of the first to fifth semiconductor dies CH1 to CH5 may be referred to as a ‘semiconductor chip’. The first semiconductor die CH1 may have a width that is larger than a width of each of the second to fifth semiconductor dies CH2 to CH5. For example, the first semiconductor die CHI may be a buffer die or a logic die.

The second to fifth semiconductor dies CH2 to CH5 may be memory chips or memory dies that are of the same kind. For example, each of the second to fifth semiconductor dies CH2 to CH5 may be a FLASH memory chip, a DRAM chip, an SRAM chip, an EEPROM chip, a PRAM chip, an MRAM chip, or an ReRAM chip. The semiconductor package 100 is illustrated to have a structure, in which four memory dies (e.g., CH2 to CH5) are stacked on one buffer die (e.g., CH1), but the present inventive concept is not limited to this example. The semiconductor package 100 may have a structure, in which three or fewer memory dies or five or more memory dies are stacked.

The first semiconductor die CH1 may include a first semiconductor substrate SB1. The first semiconductor substrate SB1 may have a front surface SB1_F and a rear surface SB1_B, which are opposite to each other. Transistors may be disposed on the front surface SB1_F of the first semiconductor substrate SB1. The front surface SB1_F of the first semiconductor substrate SB1 may be covered with a first interlayer insulating layer IL1. For example, the first interlayer insulating layer IL1 may be formed of or include at least one of SiO₂, SiN, SiON, SiCN, or SiOCH and may have a single-or multi-layered structure. First interconnection lines IT1 may be disposed in the first interlayer insulating layer IL1, and at least one of them may be connected to the transistors.

A bottom surface of the first interlayer insulating layer IL1 may be covered with a first front-side protection layer IF1. For example, the first front-side protection layer IF1 may be formed of or include at least one of SiO₂, SiN, SiON, or SiCN and may have a single-or multi-layered structure. First front-side conductive pads FC1 may be disposed in the first front-side protection layer IF1. For example, the first front-side conductive pads FC1 may be formed of or include at least one of copper, aluminum, nickel, or gold and may have a single-or multi-layered structure. Outer connection terminals OM may be bonded to the first front-side conductive pads FC1. Each of the outer connection terminals OM may include at least one of a conductive bump and a solder ball. For example, the conductive bump may include copper. For example, the solder ball may include SnAg.

The rear surface SB1_B of the first semiconductor substrate SB1 may be covered with a first back-side protection layer IB1. For example, the first back-side protection layer IB1 may be formed of or include at least one of SiO₂, SiN, SiON, or SiCN and may have a single-or multi-layered structure. First back-side conductive pads BC1 may be disposed in the first back-side protection layer IB1. For example, the first back-side conductive pads BC1 may include copper.

First through vias TV1 may be provided to penetrate the first semiconductor substrate SB1 and to connect some of the first interconnection lines IT1 to the first back-side conductive pads BC1. First via insulating layers TL1 may be respectively interposed between the first through vias TV1 and the first semiconductor substrate SB1. The first through vias TV1 may include a metallic material (e.g., tungsten). The first via insulating layers TL1 may include an insulating material (e.g., silicon oxide).

Each of the second to fifth semiconductor dies CH2 to CH5 may include a second semiconductor substrate SB2. The second semiconductor substrate SB2 may have a front surface SB2_F and a rear surface SB2_B, which are opposite to each other. Transistors TR may be disposed on the front surface SB2_F of the second semiconductor substrate SB2. For example, each of the transistors TR may be a planar-type transistor, a buried channel array transistor (BCAT), a vertical channel transistor (VCT), a fin field-effect transistor (FinFET), a vertical field-effect transistor (VFET), or a multi-bridge channel field effect transistor (MBCFET).

The front surface SB2_F of the second semiconductor substrate SB2 may be covered with a second interlayer insulating layer IL2. For example, the second interlayer insulating layer IL2 may be formed of or include at least one of SiO₂, SiN, SiON, SiCN, or SiOCH and may have a single-or multi-layered structure. Second interconnection lines IT2 may be disposed in the second interlayer insulating layer IL2, and some of them may be connected to the transistors TR.

Referring to FIG. 2A, a bottom surface of the second interlayer insulating layer IL2 may be covered with a second front-side protection layer IF2. The second front-side protection layer IF2 may include a first sub-protection layer 25a and a second sub-protection layer 25b sequentially stacked on each other. The first sub-protection layer 25a may be placed between the second sub-protection layer 25b and the second interlayer insulating layer IL2. The first sub-protection layer 25a may be formed of, for example, SiO₂. The second sub-protection layer 25b may be formed of, for example, SiCN.

A bonding pad BP may be disposed on the bottom surface of the second interlayer insulating layer IL2. The bonding pad BP may be formed of or include a metallic material (e.g., aluminum). The bonding pad BP may be covered with the first sub-protection layer 25a. A second front-side conductive pad FC2 may be disposed below the bonding pad BP. The second front-side conductive pad FC2 penetrate the second sub-protection layer 25b and a portion of the first sub-protection layer 25a and may be connected with the bonding pad BP. For example, the second front-side conductive pad FC2 may be in contact with the bonding pad BP. Side and top surfaces of the second front-side conductive pad FC2 may be covered with a front-side diffusion barrier layer FDL.

In each of the second to fourth semiconductor dies CH2 to CH4, the rear surface SB2_B of the second semiconductor substrate SB2 may be covered with a second back-side protection layer IB2. For example, the second back-side protection layer IB2 may be formed of or include at least one of SiO₂, SIN, SiON, or SiCN and may have a single-or multi-layered structure. Second back-side conductive pads BC2 may be disposed in the second back-side protection layer IB2. Side and bottom surfaces of the second back-side conductive pad BC2 may be covered with a back-side diffusion barrier layer BDL.

In each of the second to fourth semiconductor dies CH2 to CH4, second through vias TV2 may penetrate the second semiconductor substrate SB2 to connect some of the second interconnection lines IT2 to the second back-side conductive pads BC2. Second via insulating layers TL2 may be respectively interposed between the second through vias TV2 and the second semiconductor substrate SB2. The second through vias TV2 may include a metallic material (e.g., tungsten). The second via insulating layers TL2 may include an insulating material (e.g., silicon oxide).

The fifth semiconductor die CH5, which is the uppermost one of the second to fifth semiconductor dies CH2 to CH5, may have a structure, in which the second back-side protection layer IB2, the second back-side conductive pads BC2, the second through vias TV2, and the second via insulating layers TL2 are absent.

The second front-side conductive pads FC2 of one of the second to fifth semiconductor dies CH2 to CH5 may be in contact with the second back-side conductive pads BC2, respectively, of an adjacent one of the second to fourth semiconductor dies CH2 to CH4. For example, the second back-side conductive pads BC2 of the second semiconductor die CH2 may be in contact with corresponding ones of the second front-side conductive pads FC2 of the third semiconductor die CH3 thereon. For example, the second front-side conductive pad FC2 and the second back-side conductive pad BC2, which are paired and are in contact with each other, may be fused together to form a single object without an interface therebetween; however, the present inventive concept is not limited thereto.

A width of the second back-side conductive pads BC2 may be equal to or different from a width of the second front-side conductive pads FC2. For example, the width of the second back-side conductive pads BC2 may be larger than the width of the second front-side conductive pads FC2. In addition, the width of the second back-side conductive pads BC2 may be smaller than the width of the second front-side conductive pads FC2. In the case where the width of the second back-side conductive pads BC2 is different from the width of the second front-side conductive pads FC2, a misalignment margin may be increased.

The second front-side conductive pads FC2 of the second semiconductor die CH2, which is the lowermost one of the second to fifth semiconductor dies CH2 to CH5, may be in contact with the first back-side conductive pads BC1 of the first semiconductor die CH1, respectively.

Referring to FIG. 2A, each of the second front-side conductive pads FC2 and the second back-side conductive pads BC2 may be formed of a first metal. The second front-side conductive pads FC2 may further include atoms MP of a second metal different from the first metal. The first metal may be, for example, copper. The atoms MP of the second metal may be, for example, titanium. A concentration of the atoms MP of the second metal in the second front-side conductive pads FC2 may decrease as a distance from the second back-side conductive pads BC2, which are bonded to the second front-side conductive pads FC2, increases. The concentration of the atoms MP of the second metal in the second front-side conductive pads FC2 may decrease as a distance to the second interlayer insulating layer IL2, which is adjacent to the second front-side conductive pads FC2, decreases.

The atoms MP of the second metal may be absent in the second back-side conductive pads BC2, as shown in FIG. 2A. In addition, a small amount of the atoms MP of the second metal may be present in the second back-side conductive pads BC2, as shown in FIG. 2B. The concentration of the atoms MP of the second metal in the second back-side conductive pads BC2 may decrease as a distance to the rear surface SB2_B of the second semiconductor substrate SB2, which is adjacent to the second back-side conductive pads BC2, decreases.

The front-side diffusion barrier layer FDL may include a metallic material that is different from the back-side diffusion barrier layer BDL. For example, the front-side diffusion barrier layer FDL may include a third metal that is different from the first metal and the second metal. The third metal may be, for example, tantalum. The back-side diffusion barrier layer BDL may include, for example, the second metal.

A dummy die DD may be disposed on the fifth semiconductor die CH5, which is the uppermost one of the second to fifth semiconductor dies CH2 to CH5. The dummy die DD may be formed of the same material (e.g., silicon) as the second semiconductor substrate SB2. The second semiconductor substrate SB2 may have a first thickness TH1. The dummy die DD may have a second thickness TH2, which is larger than the first thickness TH1. Electrical circuits might not be disposed in the dummy die DD. The dummy die DD may be used as a stiffener for preventing or suppressing a warpage issue from occurring in the first to fifth semiconductor dies CH1 to CH5.

An adhesive layer AD may be interposed between the dummy die DD and the fifth semiconductor die CH5. The adhesive layer AD may include, for example, an epoxy-based material.

The mold layer MD may cover side surfaces of the second to fifth semiconductor dies CH2 to CH5, the adhesive layer AD, and the dummy die DD and a top surface of the first semiconductor die CH1. The mold layer MD may include an insulating resin (e.g., an epoxy-based molding compound (EMC)). The mold layer MD may further include fillers, and the fillers may be dispersed in the insulating resin. A top surface of the dummy die DD may be substantially coplanar with a top surface of the mold layer MD.

In an embodiment of the present inventive concept, the first to fifth semiconductor dies CH1 to CH5 in the semiconductor package 100 may have an improved topology and may have a flat shape. Furthermore, it may be possible to prevent a non-bonding issue between the first to fifth semiconductor dies CH1 to CH5, a void issue, and a crack issue, and thus, the reliability of the semiconductor package 100 may be increased.

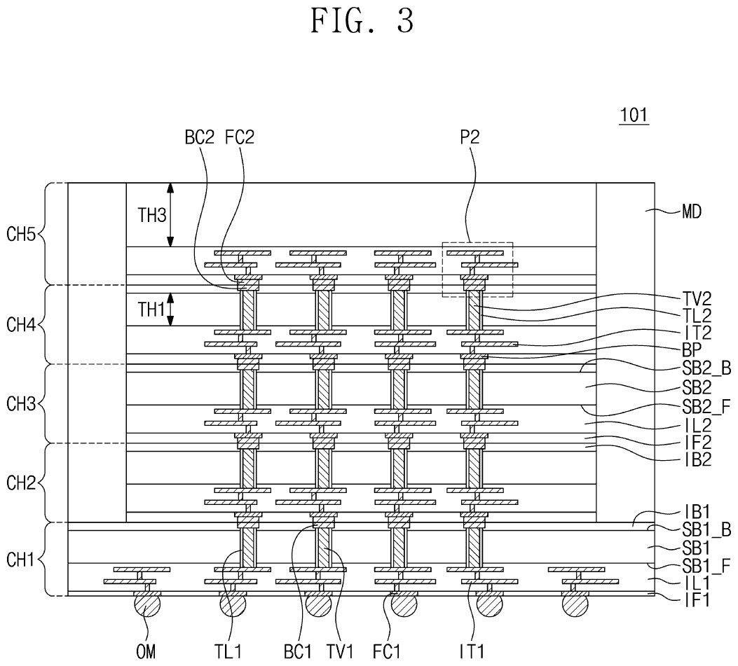

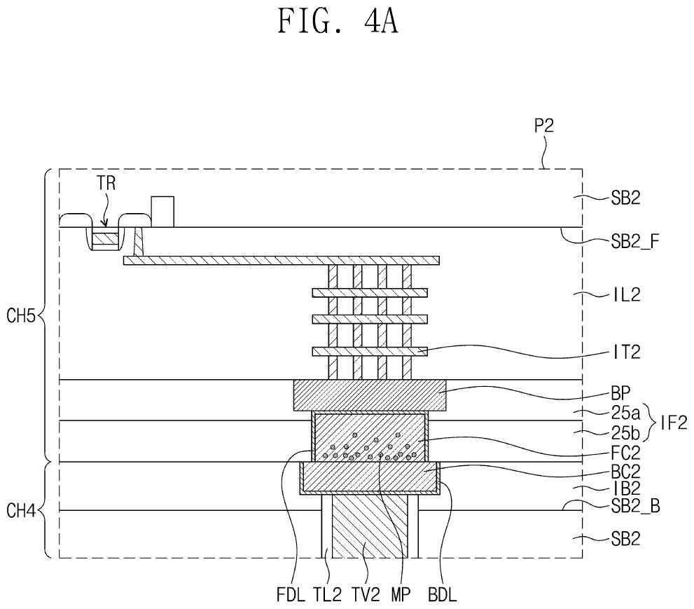

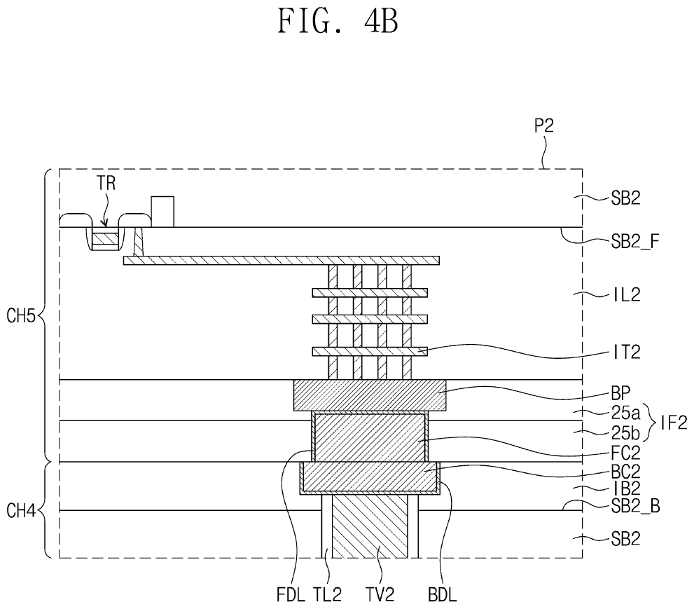

FIG. 3 is a cross-sectional view illustrating a semiconductor package according to an embodiment of the present inventive concept. FIGS. 4A and 4B are enlarged cross-sectional views illustrating a portion ‘P2’ of FIG. 3.

Referring to FIGS. 3, 4A, and 4B, a semiconductor package 101 according to the present embodiment may have a structure, in which the dummy die DD and the adhesive layer AD of FIG. 1 are not provided. The rear surface SB2_B of the second semiconductor substrate SB2 of the fifth semiconductor die CH5 may be substantially coplanar with the top surface of the mold layer MD. Each of the second semiconductor substrates SB2 of the second to fourth semiconductor dies CH2 to CH4 may have a first thickness TH1, and the second semiconductor substrate SB2 of the fifth semiconductor die CH5 may have a second thickness TH2 that is larger than or equal to the first thickness TH1. The second front-side conductive pad FC2 of the fifth semiconductor die CH5 may include the atoms MP of the second metal, as shown in FIG. 4A, and a concentration of the atoms MP of the second metal may decrease as a distance to the second interlayer insulating layer IL2, which is adjacent thereto, decreases. In addition, the second front-side conductive pad FC2 of the fifth semiconductor die CH5 might not contain the atoms MP of the second metal, as shown in

FIG. 4B. Except for the afore-described differences, the semiconductor package may have substantially the same or similar features as those in the previous embodiments.

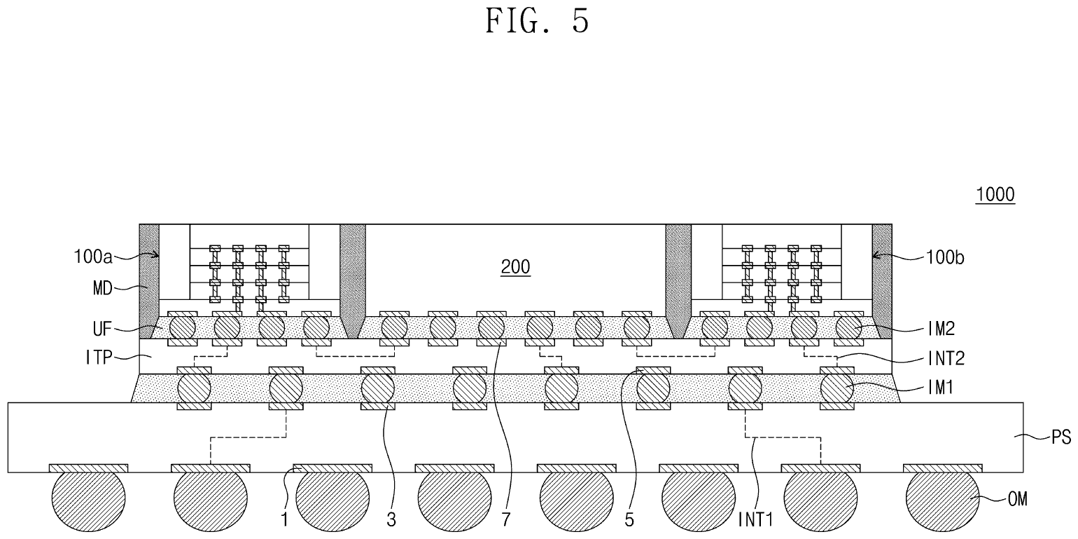

FIG. 5 is a cross-sectional view illustrating a semiconductor package according to an embodiment of the present inventive concept.

Referring to FIG. 5, a semiconductor package 1000 according to an embodiment of the present inventive concept may include a package substrate PS, an interposer substrate ITP, a first sub-semiconductor package 200, second sub-semiconductor packages 100a and 100b, and a mold layer MD. The package substrate PS may be a double-sided or multi-layered printed circuit board. The package substrate PS may include first upper substrate pads 3, first lower substrate pads 1, and first inner interconnection lines INT1. For example, each of the first upper substrate pads 3, the first lower substrate pads 1, and the first inner interconnection lines INT1 may be formed of or include at least one of metallic materials (e.g., copper, aluminum, or gold). The first inner interconnection lines INT1 may connect at least some of the first upper substrate pads 3 to the first lower substrate pads 1. The outer connection terminals OM may be bonded to the first lower substrate pads 1.

The interposer substrate ITP may be placed on the package substrate PS. For example, the interposer substrate ITP may be formed of or include silicon. The interposer substrate ITP may be a semiconductor die. The interposer substrate ITP may include second upper substrate pads 7, second lower substrate pads 5, and second inner interconnection lines INT2. For example, each of the second upper substrate pads 7, the second lower substrate pads 5, and the second inner interconnection lines INT2 may include at least one of metallic materials (e.g., copper, aluminum, and tungsten). Some of the second inner interconnection lines INT2 may connect some of the second upper substrate pads 7 to the second lower substrate pads 5. Others of the second inner interconnection lines INT2 may connect the second sub-semiconductor packages 100a and 100b to the first sub-semiconductor package 200.

The interposer substrate ITP may be electrically connected to the package substrate PS by first inner connection members IM1. The first inner connection members IM1 may be solder balls. An under-fill layer UF may be interposed between the interposer substrate ITP and the package substrate PS.

The first sub-semiconductor package 200 and the second sub-semiconductor packages 100a and 100b may be disposed on the interposer substrate ITP. The first sub-semiconductor package 200 may be disposed between the second sub-semiconductor packages 100a and 100b. For example, the first sub-semiconductor package 200 may be a large scale integration (LSI) chip, a logic circuit chip, a processor chip, or an application-specific integrated circuit (ASIC) semiconductor chip. For example, the second sub-semiconductor packages 100a and 100b may be a memory chip (e.g., a high bandwidth memory (HBM) chip or a hybrid memory cubic (HMC) chip). The second sub-semiconductor packages 100a and 100b may have the same or similar structure as that of the semiconductor package 100 or 101 described with reference to FIGS. 1 to 4B. The first sub-semiconductor package 200 may be configured to store data in the second sub-semiconductor packages 100a and 100b or to process and compute data that is stored in the second sub-semiconductor packages 100a and 100b.

The first sub-semiconductor package 200 and the second sub-semiconductor packages

100a and 100b may be electrically connected to the interposer substrate ITP by second inner connection members IM2. The second inner connection members IM2 may be solder balls. The under-fill layer UF may be interposed between the interposer substrate ITP and the first sub-semiconductor package 200 and between the interposer substrate ITP and the second sub-semiconductor packages 100a and 100b. A space between the first sub-semiconductor package 200 and the second sub-semiconductor packages 100a and 100b may be filled with the mold layer MD.

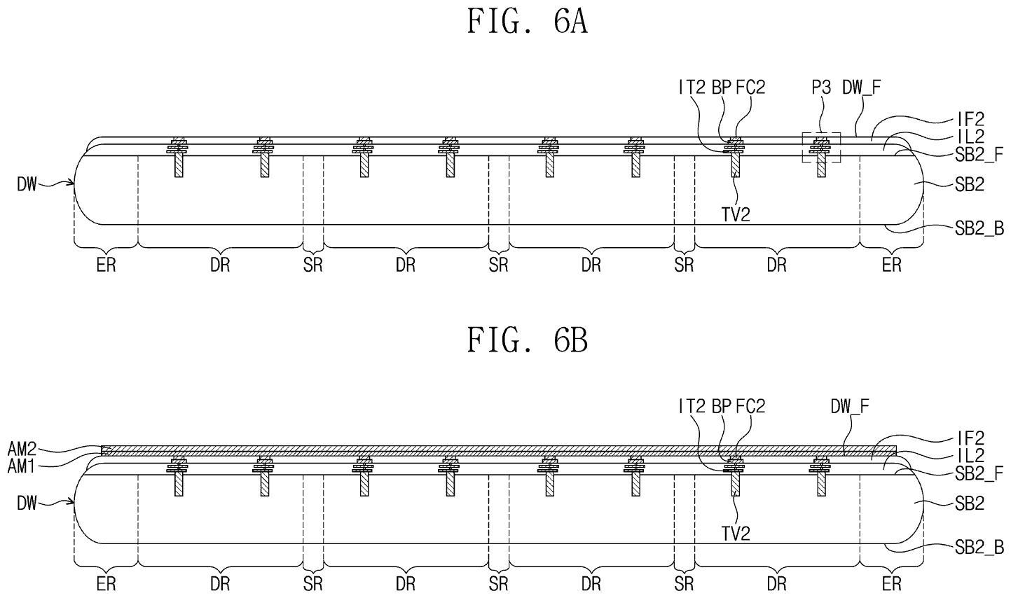

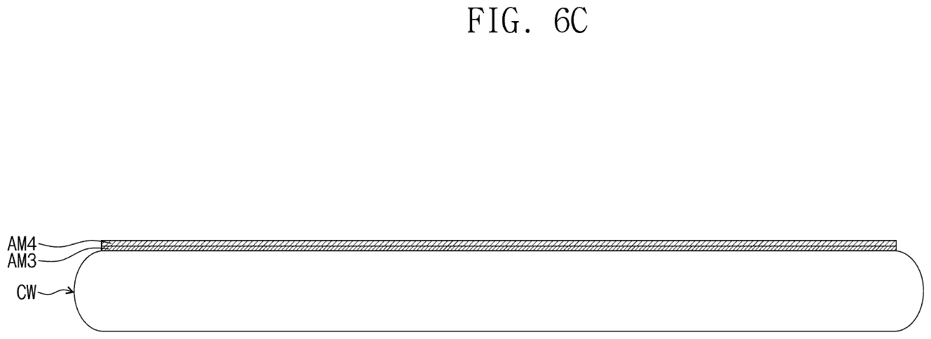

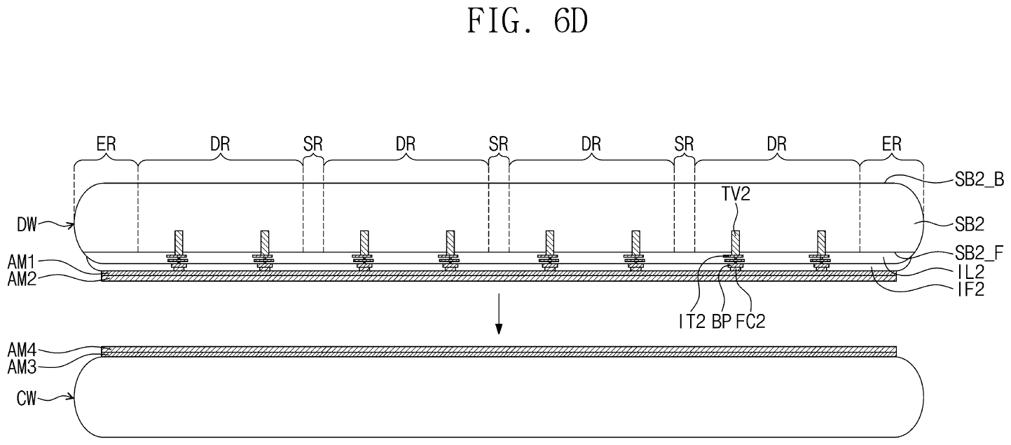

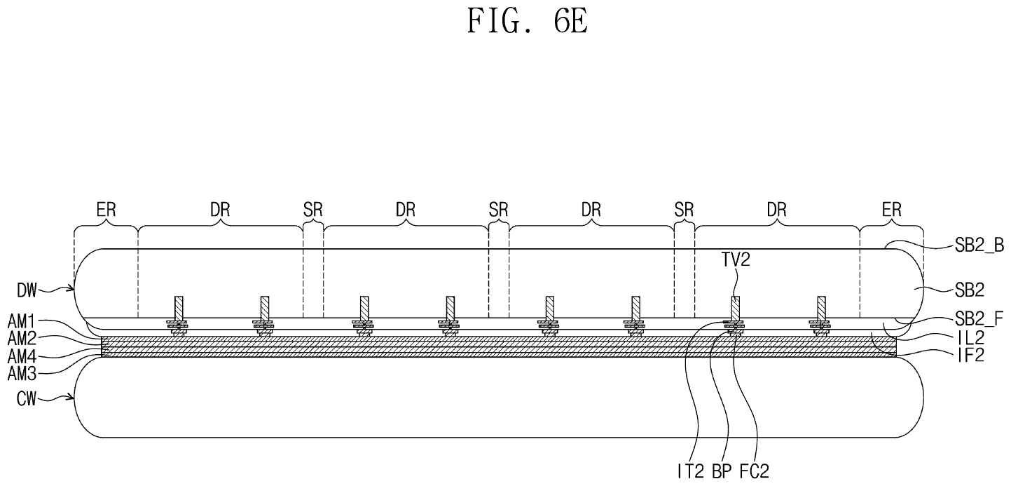

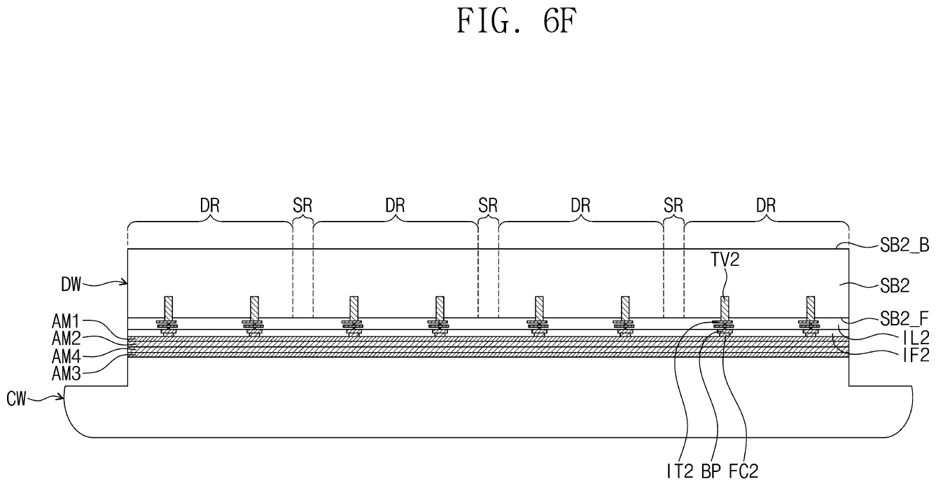

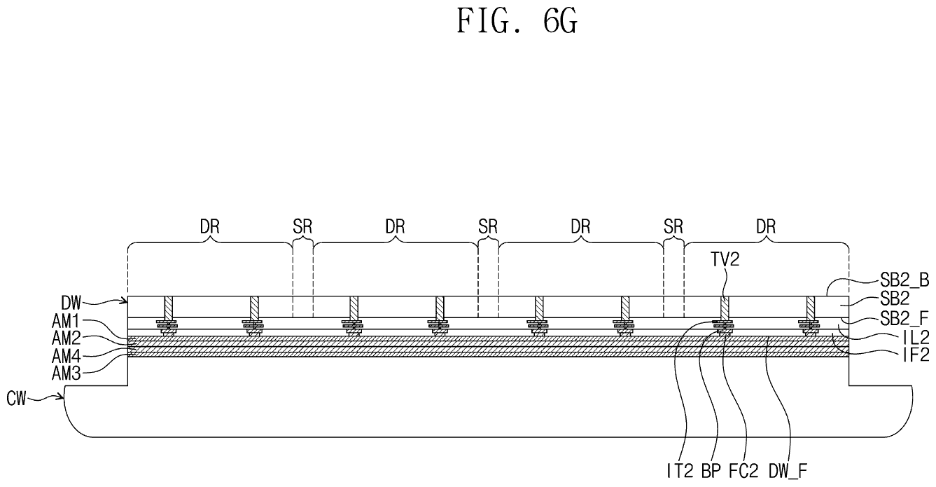

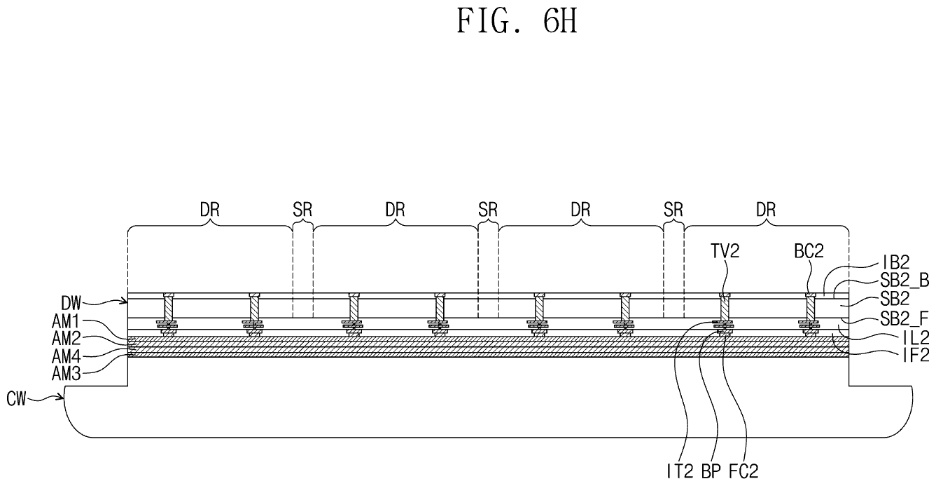

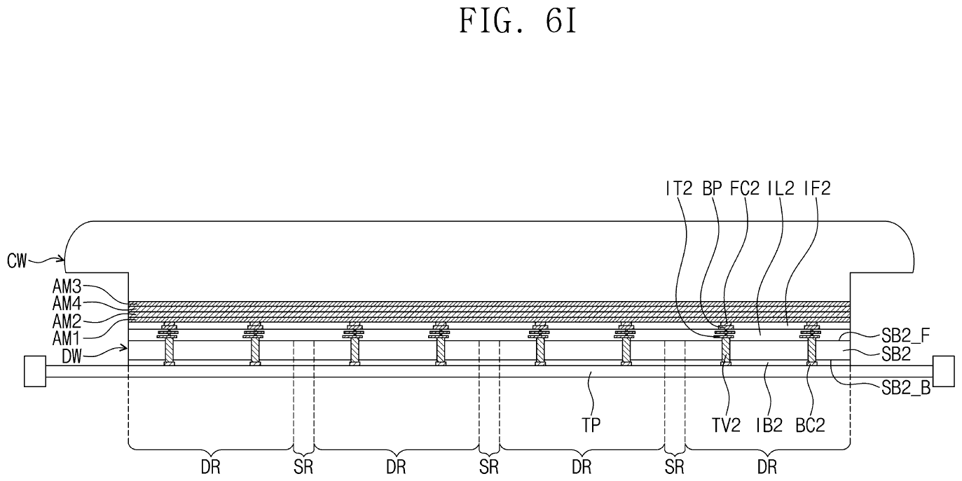

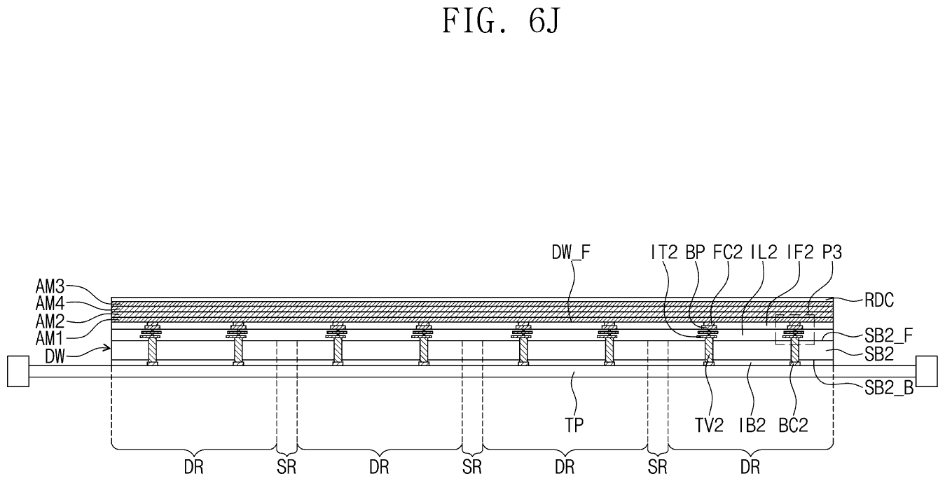

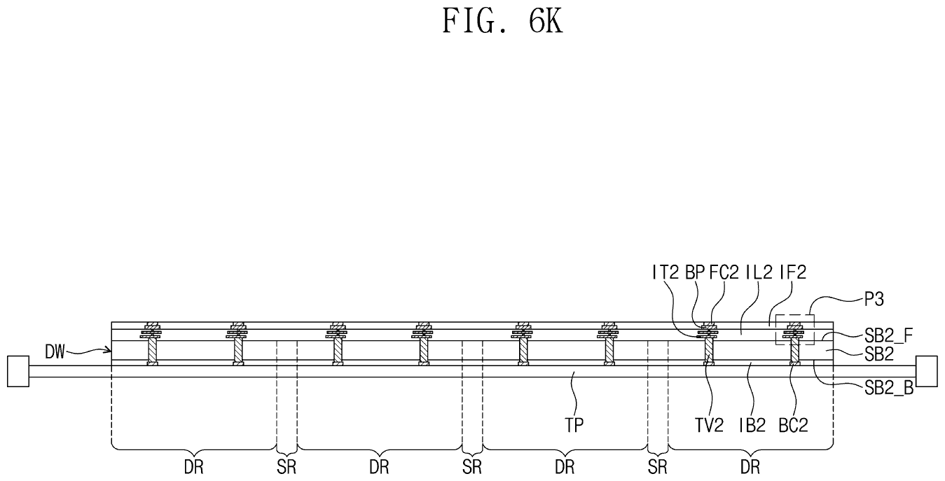

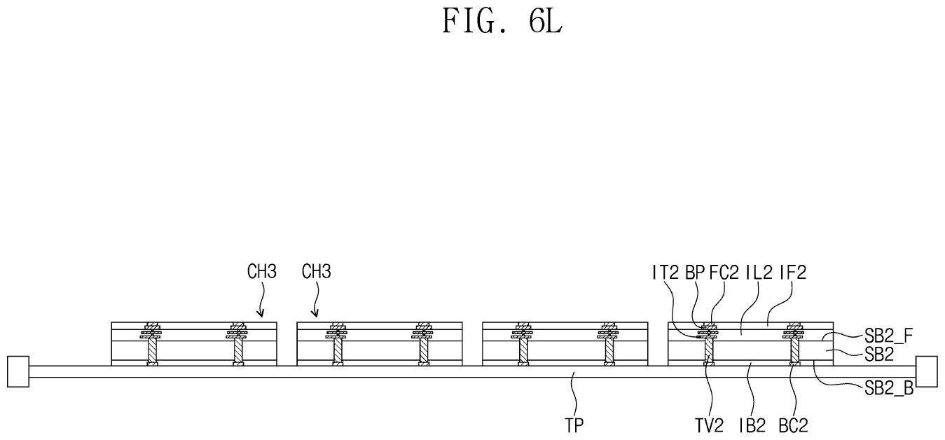

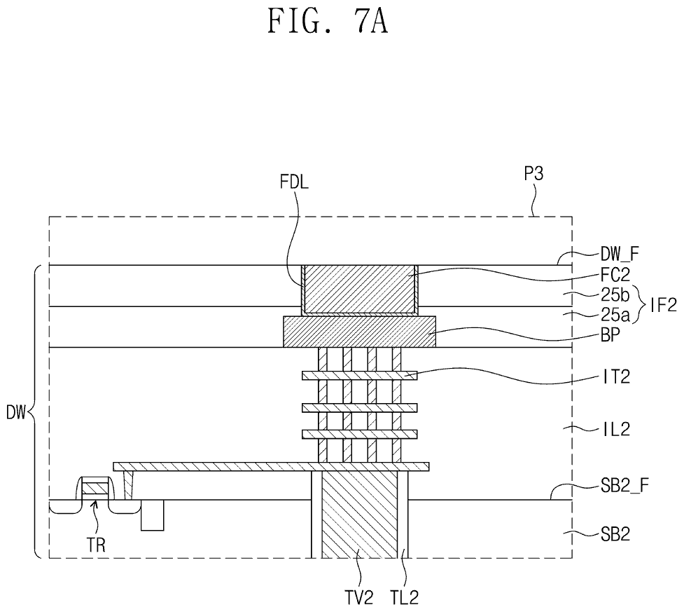

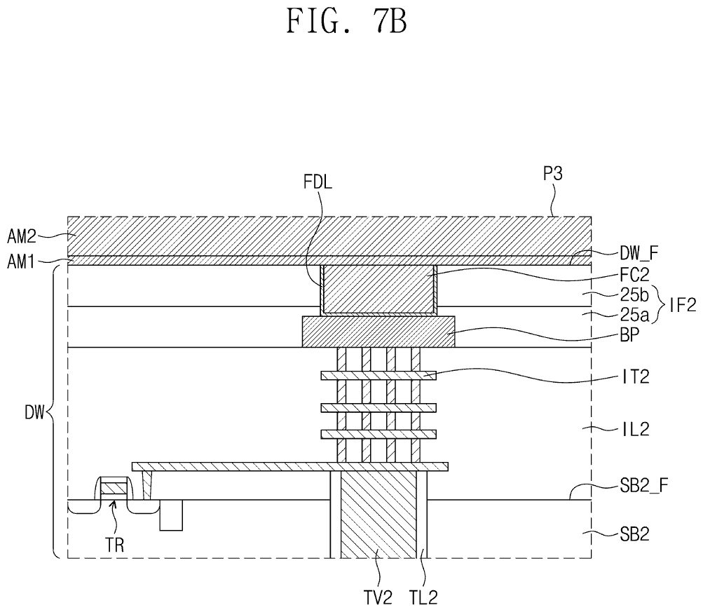

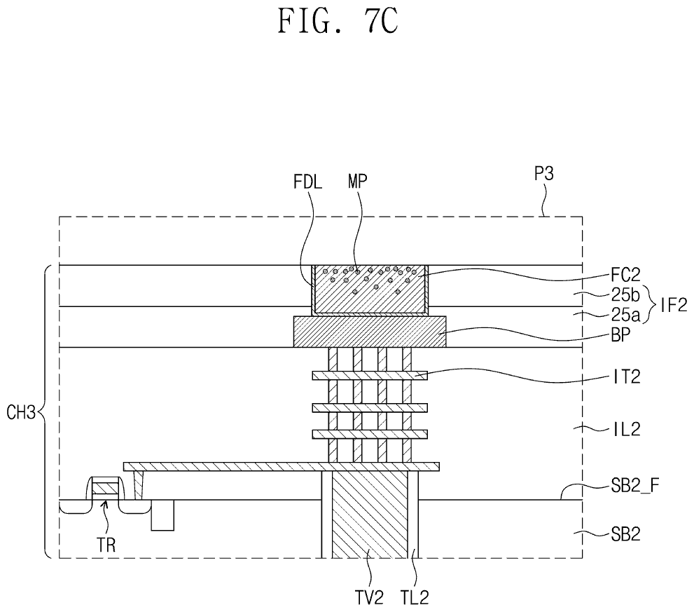

FIGS. 6A to 6L are cross-sectional views illustrating a process of fabricating the semiconductor dies of FIG. 1 or 3. FIG. 7A is an enlarged sectional view illustrating a portion ‘P3’ of FIG. 6A. FIG. 7B is an enlarged sectional view illustrating a portion ‘P3’ of FIG. 6J. FIG. 7C is an enlarged sectional view illustrating a portion ‘P3’ of FIG. 6K.

Referring to FIGS. 6A and 7A, a device wafer DW may be prepared. The device wafer DW may include the second semiconductor substrate SB2. The second semiconductor substrate SB2 may have the front surface SB2_F and the rear surface SB2_B, which are opposite to each other. The second semiconductor substrate SB2 may include a plurality of device regions DR and a separation region SR between adjacent device regions DR of the plurality of device regions DR. The second semiconductor substrate SB2 may further include edge regions ER. The front surface SB2_F of the second semiconductor substrate SB2 may be covered with the second interlayer insulating layer IL2 and the second front-side protection layer IF2. In the device region DR, the transistors TR, the second through vias TV2, the second interconnection lines IT2, the bonding pads BP, the front-side diffusion barrier layer FDL, and the second front-side conductive pads FC2 may be disposed on the front surface SB2_F of the second semiconductor substrate SB2. For example, the front-side diffusion barrier layer FDL may be formed of or include at least one of tantalum or tantalum nitride and may have a single-or multi-layered structure. The second front-side conductive pads FC2 may be formed of copper. The process of forming the second front-side conductive pads FC2 may include a plating process and a chemical mechanical polishing (CMP) process. As a result of the CMP process, a front surface DW_F of the device wafer DW may have an improved topology and a flat shape. The rear surface SB2_B of the second semiconductor substrate SB2 may be referred to as a rear surface of the device wafer DW.

Referring to FIGS. 6B and 7B, a first metal layer AM1 and a second metal layer AM2 may be sequentially stacked on the front surface DW_F of the device wafer DW. The first metal layer AM1 and the second metal layer AM2 may be formed by a deposition process (e.g., a physical vapor deposition (PVD) process or a sputtering process). The first metal layer AM1 may exhibit better (e.g., stronger or higher) adhesion or affinity properties to the front surface DW_F of the device wafer DW or the surface of the second front-side protection layer IF2, compared with the second metal layer AM2. The first metal layer AM1 may be formed of a material having an etch selectivity with respect to the second metal layer AM2 and the second front-side conductive pad FC2. In an embodiment of the present inventive concept, the first metal layer AM1 may be formed of a second metal (e.g., titanium), and the second metal layer AM2 may be formed of a first metal (e.g., copper). A thickness of the first metal layer AM1 may range from about 1 Å to about 100 Å.A thickness of the second metal layer AM2 may range from about 10 Å to about 500 Å.

Referring to FIG. 6C, a carrier substrate CW may be prepared. The carrier substrate CW may be a bare wafer. A third metal layer AM3 and a fourth metal layer AM4 may be sequentially stacked on the carrier substrate CW. The third metal layer AM3 may exhibit better (e.g., stronger or higher) adhesion or affinity properties to the surface of the carrier substrate CW, compared with the fourth metal layer AM4. The third metal layer AM3 may be formed of a material having an etch selectivity with respect to the fourth metal layer AM4. In an embodiment of the present inventive concept, the third metal layer AM3 may be formed of the second metal (e.g., titanium), and the fourth metal layer AM4 may be formed of the first metal (e.g., copper). A thickness of the third metal layer AM3 may range from about 1 Å to about 100 Å. A thickness of the fourth metal layer AM4 may range from about 10 Å to about 500 Å.

Referring to FIGS. 6D and 6E, the device wafer DW may be inverted such that the front surface DW_F of the device wafer DW faces a top surface of the carrier substrate CW. Thereafter, the second metal layer AM2 that is disposed on the front surface DW_F of the device wafer DW may be disposed on the fourth metal layer AM4 that is disposed on the carrier substrate CW. For example, the second metal layer AM2 may be in contact with the fourth metal layer AM4. A thermocompression process may be performed to bond the second metal layer AM2 to the fourth metal layer AM4 in a Cu-to-Cu manner. For example, the second and fourth metal layers AM2 and AM4, which are bonded to each other, may be fused to form a single body without an observable interface therebetween. Since the bonding structure between the second and fourth metal layers AM2 and AM4 is a metal bonding structure, a bonding strength therebetween may be increased. A sum of the thicknesses of the first to fourth metal layers AM1 to AM4 may be less than about 1000 Å.

Referring to FIGS. 6E and 6F, an edge trimming process may be performed to remove the

edge regions ER of the device wafer DW, edge portions of the first to fourth metal layers AM1 to AM4 thereunder, and edge portions of the carrier substrate CW thereunder.

Referring to FIGS. 6F and 6G, a back grinding process may be performed on the rear surface SB2_B of the device wafer DW to remove a portion of the second semiconductor substrate SB2 and to expose the second through vias TV2. Since the device wafer DW is bonded to the carrier substrate CW in a robust metal bonding manner (e.g., a Cu-to-Cu manner), it may be possible to prevent a surface topology of the front surface DW_F of the device wafer DW from being deteriorated by a stress in the back grinding process.

Referring to FIGS. 6G and 6H, an etch-back process may be performed on the rear surface SB2_B of the second semiconductor substrate SB2 to remove a portion of the second semiconductor substrate SB2, and in this case, portions of the second through vias TV2 may protrude beyond the rear surface SB2_B of the second semiconductor substrate SB2. The second back-side protection layer IB2 may be formed on the rear surface SB2_B of the second semiconductor substrate SB2. Next, the back-side diffusion barrier layer BDL and the second back-side conductive pad BC2 may be formed in the second back-side protection layer IB2. The process of forming the second back-side conductive pad BC2 may include a plating process and a chemical mechanical polishing (CMP) process. As a result of the CMP process, a top surface of the second back-side protection layer IB2 may have an improved topology and a flat shape. Referring to FIGS. 6H and 6I, the device wafer DW and the carrier substrate CW, which are bonded to each other, may be inverted, and then, the second back-side protection layer IB2 may be bonded to a tape carrier TP. Thus, the carrier substrate CW may be placed on the device wafer DW.

Referring to FIGS. 6I and 6J, a grinding process may be performed to remove most of the

carrier substrate CW and to leave a remaining substrate layer RDC. The remaining substrate layer RDC may correspond to a portion of the carrier substrate CW and may be formed of, for example, silicon. Since the device wafer DW is bonded to the carrier substrate CW in a robust metal bonding manner (e.g., a Cu-to-Cu manner), it may be possible to prevent a surface topology of the front surface DW_F of the device wafer DW from being deteriorated by a stress in the grinding process.

Referring to FIGS. 6J and 6K, a dry etching process may be performed to remove the remaining substrate layer RDC and to expose the third metal layer AM3. Here, the third metal layer AM3 may serve as an etch stop layer. An etching processes may be performed several times to sequentially remove the third metal layer AM3, the fourth metal layer AM4, the second metal layer AM2, and the first metal layer AM1 and to expose a top surface of the second front-side protection layer IF2 and top surfaces of the second front-side conductive pads FC2. For example, the third metal layer AM3, the fourth metal layer AM4, the second metal layer AM2, and the first metal layer AM1 may be completely removed. For example, the etching processes may be performed in a dry or wet manner and in an anisotropic or isotropic manner. The etching processes might not deteriorate the surface topology of the front surface DW_F of the device wafer DW.

Some atoms of the second metal (e.g., titanium) in the first metal layer AM1 may be diffused into the second front-side conductive pads FC2. Thus, the second front-side conductive pads FC2 may include the atoms MP of the second metal. A concentration of the atoms MP of the second metal in the second front-side conductive pads FC2 may be higher when closer to the first metal layer AM1 and lower when closer to the second interlayer insulating layer IL2.

Referring to FIGS. 6K and 6L, a chip singulation process, such as a sawing process or a dicing process, may be performed to cut the separation region SR of the device wafer DW and to leave the device regions DR, and as a result, a plurality of semiconductor dies CH3 may be formed.

The first to fourth semiconductor dies CH1 to CH4 of FIG. 1 may be fabricated through substantially the same process as described with reference to FIGS. 6A to 6L. The fifth semiconductor die CH5 of FIG. 1 may be fabricated through substantially the same process as described with reference to FIGS. 6A to 6L, but the second through vias TV2 of FIG. 6A may be omitted from the fifth semiconductor die CH5. In addition, the fifth semiconductor die CH5 of

FIG. 1 may be fabricated by performing a chip singulation process on the device wafer DW, which does not include the second through vias TV2 of FIG. 6A. If the first to fifth semiconductor dies CH1 to CH5 are fabricated through this process, the first to fifth semiconductor dies CH1 to CH5 may be stacked, as shown in FIG. 1, and then, a thermocompression process may be performed to bond the first to fifth semiconductor dies CH1 to CH5 to each other. Next, the mold layer MD may be formed, and the outer connection terminals OM may be bonded to the resulting structure. As a result, the semiconductor package 100 of FIG. 1 may be fabricated.

In a method of fabricating a semiconductor package according to an embodiment of the present inventive concept, since the device wafer DW and the carrier substrate CW are bonded to each other in a Cu-to-Cu manner by using the first to fourth metal layers AM1 to AM4, the device wafer DW may be robustly bonded to the carrier substrate CW, and thus, it may be possible to prevent the topology of the front and rear surfaces of the device wafer DW from being deteriorated in the grinding processes. Accordingly, each of the semiconductor dies CH1 to CH5 in the semiconductor packages 100 and 101 may have an improved topology and a flat shape, and this may make it possible to reduce or prevent a process failure (e.g., a non-bonding issue between the semiconductor dies CH1 to CH5, a void issue, or a crack issue) and to increase the reliability of the semiconductor packages 100 and 101.

In a method of fabricating a semiconductor package according to an embodiment of the

present inventive concept, since an epoxy-based glue layer is not used to bond the device wafer to the carrier substrate, it may be possible to reduce a variation in thickness of the device wafer DW or the second front-side conductive pads FC2. Since the front surface DW_F of the device wafer DW is flat, it may be unnecessary to perform a polishing process on the front surface DW_F of the device wafer DW, after the back grinding process on the device wafer DW. Thus, the fabrication process may be simplified. This may make it possible to reduce or prevent a process failure and to increase a fabrication yield.

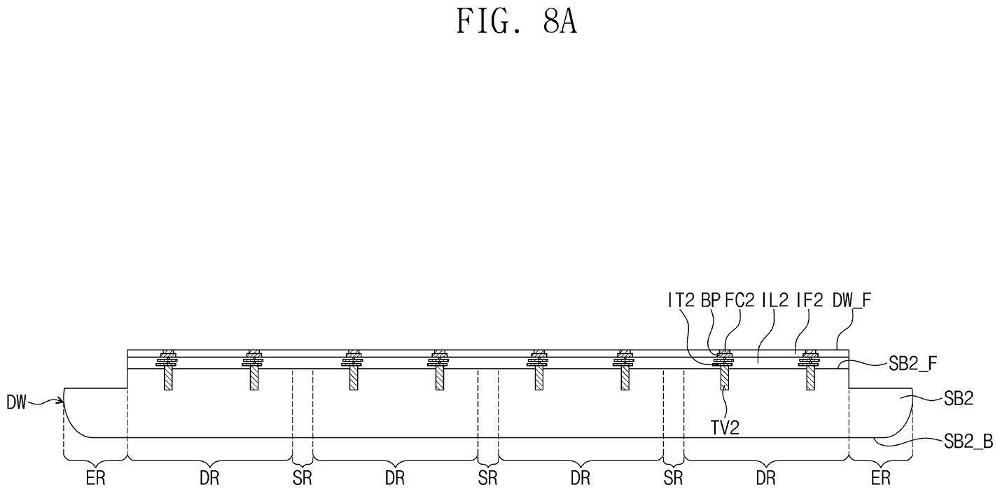

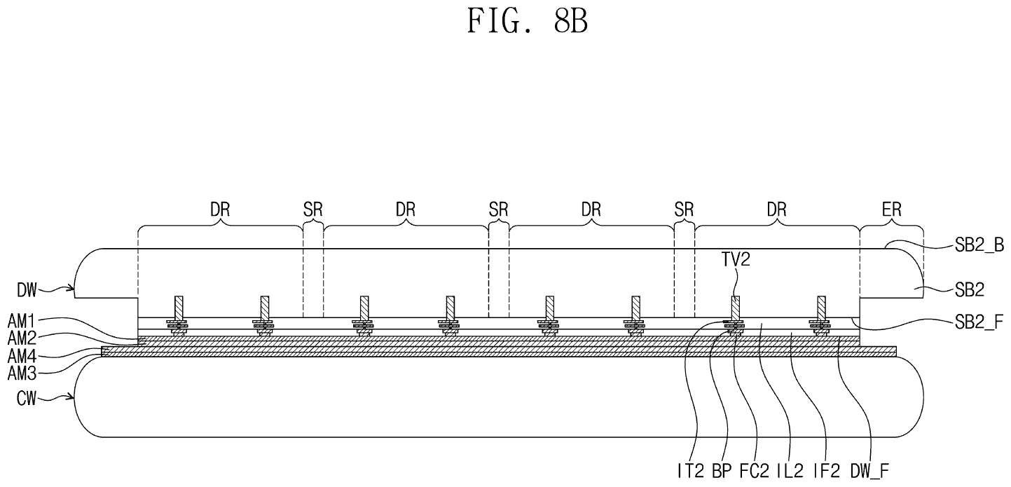

FIGS. 8A and 8B are cross-sectional views illustrating a process of fabricating the semiconductor dies of FIG. 1 or 3.

Referring to FIG. 8A, the edge trimming process may be performed on the device wafer DW to partially remove the edge regions ER of the device wafer DW, in the step of FIG. 6A.

Referring to FIG. 8B, the first metal layer AM1 and the second metal layer AM2 may be sequentially stacked on the front surface DW_F of the device wafer DW. The third metal layer AM3 and the fourth metal layer AM4 may be sequentially stacked on the carrier substrate CW. Next, the device wafer DW may be inverted and then may be bonded to the carrier substrate CW.

Thereafter, the processes of FIGS. 6G to 6L may be performed to fabricate the semiconductor dies.

In a semiconductor package according to an embodiment of the present inventive concept, semiconductor dies may be provided to have an improved topology and a flat shape, and thus, it may be possible to reduce a variation in thickness of the semiconductor dies. This may make it possible to prevent a non-bonding issue between the semiconductor dies, a void issue, a crack issue, and a warpage, and reliability of the semiconductor package may be increased.

In a method of fabricating a semiconductor package according to an embodiment of the present inventive concept, a device wafer and a carrier substrate may be bonded to each other by a Cu-to-Cu method using metal layers, and thus, the device wafer and the carrier substrate may be robustly bonded to each other. Accordingly, it may be possible to prevent the topology of the device wafer from being deteriorated in grinding processes. As a result, the semiconductor dies may have an improved topology and a flat shape. Furthermore, it may be possible to reduce a process failure and to increase a fabrication yield.

While the present invention has been described with reference to embodiments thereof, it will be understood by those of ordinary skill in the art that various changes in form and details may be made thereto without departing from the spirit and scope of the present invention.

What is claimed is:

1. A semiconductor package, comprising:
first to third semiconductor dies sequentially stacked on each other; and
a mold layer covering the first to third semiconductor dies,
wherein the second semiconductor die comprises a first back-side conductive pad disposed in a top portion thereof,
the third semiconductor die comprises a first front-side conductive pad, which is disposed in a bottom portion thereof and is in contact with the first back-side conductive pad,
each of the first front-side conductive pad and the first back-side conductive pad comprises a first metal, and
the first front-side conductive pad further comprises a second metal that is different from the first metal.

2. The semiconductor package of claim 1, wherein a concentration of the second metal in the first front-side conductive pad decreases as a distance from the first back-side conductive pad increases.

3. The semiconductor package of claim 1, wherein the first metal is copper, and the second metal is titanium.

4. The semiconductor package of claim 1, wherein the first back-side conductive pad further comprises the second metal, and
a concentration of the second metal in the first back-side conductive pad decreases as a distance from the first front-side conductive pad increases.

5. The semiconductor package of claim 1, wherein each of the second and third semiconductor dies comprises:
a first semiconductor substrate having a first surface and a second surface, which are opposite to each other;
a first interlayer insulating layer covering the first surface of the first semiconductor substrate;
first interconnection lines disposed in the first interlayer insulating layer;
a first front-side protection layer covering the first interlayer insulating layer;
a first through via penetrating the first semiconductor substrate and connected to one of the first interconnection lines; and
a first back-side protection layer covering the second surface of the first semiconductor substrate,
wherein the first back-side conductive pad is placed in the first back-side protection layer of the second semiconductor die, and
the first front-side conductive pad is placed in the first front-side protection layer of the third semiconductor die.

6. The semiconductor package of claim 5, further comprising a fourth semiconductor die disposed on the third semiconductor die,
wherein the third semiconductor die further comprises a second back-side conductive pad disposed in the first back-side protection layer,
the fourth semiconductor die comprises:
a second semiconductor substrate having a first surface and a second surface, which are opposite to each other;
a second interlayer insulating layer covering the first surface of the second semiconductor substrate;
second interconnection lines disposed in the second interlayer insulating layer;
a second front-side protection layer covering the second interlayer insulating layer; and
a second front-side conductive pad disposed in the second front-side protection layer and in contact with the second back-side conductive pad of the third semiconductor die.

7. The semiconductor package of claim 6, wherein the second back-side conductive pad and the second front-side conductive pad do not include the second metal.

8. The semiconductor package of claim 6, wherein the first semiconductor substrate has a first thickness, and
the second semiconductor substrate has a second thickness that is larger than the first thickness.

9. The semiconductor package of claim 6, further comprising:
a dummy die disposed on the fourth semiconductor die; and
an adhesive layer disposed between the dummy die and the fourth semiconductor die,
wherein the mold layer covers side surfaces of the dummy die and the adhesive layer.

10. The semiconductor package of claim 9, wherein the first semiconductor substrate has a first thickness, and
the dummy die has a second thickness that is larger than the first thickness.

11. The semiconductor package of claim 9, wherein the dummy die is formed of a same material as the first semiconductor substrate.

12. The semiconductor package of claim 1, wherein the second semiconductor die further comprises a back-side diffusion barrier layer covering the first back-side conductive pad,
the third semiconductor die further comprises a front-side diffusion barrier layer covering the first front-side conductive pad,
the back-side diffusion barrier layer comprises the second metal, and
the front-side diffusion barrier layer comprises a third metal that is different from each of the first and second metals.

13. A semiconductor package, comprising:
a first semiconductor die;
a plurality of second semiconductor dies stacked on the first semiconductor die; and
a mold layer covering side surfaces of the second semiconductor dies and a top surface of the first semiconductor die,
wherein each of the second semiconductor dies comprises:
a semiconductor substrate having a front surface and a rear surface, which are opposite to each other;
a front-side conductive pad disposed on the front surface of the semiconductor substrate;
a front-side diffusion barrier layer covering the front-side conductive pad;
a back-side conductive pad disposed on the rear surface of the semiconductor substrate; and
a back-side diffusion barrier layer covering of the back-side conductive pad,
wherein each of the front-side conductive pad and the back-side conductive pad comprises a first metal,
the back-side diffusion barrier layer comprises a second metal that is different from the first metal, and
the front-side diffusion barrier layer comprises a third metal that is different from each of the first and second metals.

14. The semiconductor package of claim 13, wherein the front-side conductive pad comprises the second metal, and
a concentration of the second metal in the front-side conductive pad decreases as a distance to the front surface of the semiconductor substrate decreases.

15. The semiconductor package of claim 13, wherein each of the second semiconductor dies comprises:
an interlayer insulating layer covering the front surface of the semiconductor substrate;
interconnection lines disposed in the interlayer insulating layer;
a front-side protection layer covering the interlayer insulating layer;
a through via penetrating the semiconductor substrate and connected to one of the interconnection lines; and
a back-side protection layer covering the rear surface of the semiconductor substrate,
wherein the back-side conductive pad is placed in the back-side protection layer, and
the front-side conductive pad is placed in the front-side protection layer.

16. The semiconductor package of claim 13, wherein the first metal is copper,
the second metal is titanium, and
the third metal is tantalum.

17. The semiconductor package of claim 13, further comprising a dummy die disposed on an uppermost one of the second semiconductor dies,
wherein the semiconductor substrate has a first thickness, and
the dummy die has a second thickness that is larger than the first thickness.

18. A semiconductor package, comprising:
a buffer die;
outer connection terminals bonded to a first surface of the buffer die;
a plurality of first memory dies stacked on the buffer die;
a second memory die disposed on an uppermost one of the first memory dies;
a dummy die disposed on the second memory die;
an adhesive layer disposed between the dummy die and the second memory die; and
a mold layer covering side surfaces of the first and second memory dies, the dummy die, and the adhesive layer and a top surface of the buffer die,
wherein each of the first memory dies comprises:
a semiconductor substrate having a front surface and a rear surface, which are opposite to each other;
an interlayer insulating layer covering the front surface of the semiconductor substrate;
interconnection lines disposed in the interlayer insulating layer;
a front-side protection layer covering the interlayer insulating layer;
a front-side conductive pad disposed in the front-side protection layer;
a front-side diffusion barrier layer covering the front-side conductive pad;
a through via penetrating the semiconductor substrate and connected to one of the interconnection lines;
a back-side protection layer covering the rear surface of the semiconductor substrate;
a back-side conductive pad disposed in the back-side protection layer; and
a back-side diffusion barrier layer covering the back-side conductive pad,
wherein the first semiconductor substrate has a first thickness,
the dummy die has a second thickness that is larger than the first thickness,
the front-side conductive pad comprises titanium, and
a concentration of the titanium in the front-side conductive pad decreases as a distance to the interlayer insulating layer decreases.

19. The semiconductor package of claim 18, wherein the front-side conductive pad further comprises copper, and
the back-side conductive pad comprises the copper and does not include the titanium.

20. The semiconductor package of claim 18, wherein the dummy die is formed of same material as the semiconductor substrate.
